(19) United States
(12) Patent Application Publication
(10) Pub. No.: US 2007/0210428 A1
(43) Pub. Date: Sep. 13, 2007

(54) Die stack system and method

(76) Inventors: Wooi Aun Tan, Georgetown (MY); Chee Koang Chen, Bayan Lepas (MY); Chin Hock Toh, Sibu (MY); Chiang Yeow Lim, Bayan Lepas (MY)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 11/373,713

(22) Filed: Mar. 9, 2006

(51) Int. Cl. H01L 23/02

(52) U.S. Cl. 257/678

(57) ABSTRACT

Embodiments of the present invention provide a die stack including a first substrate, a first die bonded to the first substrate, a second substrate having a cavity sized and shaped to fit over the first die, and a second die bonded to at least a portion of a rim of the cavity.

### TECHNICAL FIELD

Embodiments of the present invention relate to the field of integrated circuits, and more specifically, to a die stack having two or more layers and a system and a method related thereto.

### BACKGROUND

Stacking of dies in a package is limited by the overall package thickness. Wire loop height and mold-cap height add to the overall thickness of a stacked die package, further limiting the number of dies that can be stacked in a package. Further, long loop length of wirebond stacking also tends to degrade the performance of stacked die packages. Additionally, a bare silicon wafer is typically used as spacer in some die stacks. The use of bare silicon as a spacer adds cost.

Another challenge is die stack packages are tested after stacking. Consequently, a single substandard die in a package will result in substantially more significant yield loss because the entire die stack package must be scrapped.

Efforts to reduce die stack thickness include: using thinner die, using thinner substrates, using a low loop wirebonding process, and using a thinner mold-cap. However, each of these approaches includes shortcomings such as die cracking, carbon-doped oxidation (CDO) delamination, substrate warpage, requiring wirebonding module process characterization, and/or requiring molding module process characterization.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates cross sectional view of a die package in accordance with various embodiments of the present invention;

FIG. 2 illustrates cross sectional view of a die package in accordance with various embodiments of the present invention;

FIG. 3 illustrates an exploded perspective view of a die package in accordance with various embodiments of the present invention;

FIG. 4 illustrates an exploded perspective view of a die package in accordance with various embodiments of the present invention;

FIG. 5 is a cross sectional view of a die package in accordance with various embodiments of the present invention;

FIG. 6 illustrates a partial schematic and partial block diagram of a system according to various embodiments of the invention;

FIG. 7 is a flow diagram illustrating a method in accordance with various embodiments of the invention;

FIG. 8 is a flow diagram illustrating a method in accordance with various embodiments of the invention;

FIG. 9 is a flow diagram illustrating a method in accordance with one embodiment of the invention;

FIG. 10 is a flow diagram illustrating a method in accordance with one embodiment of the invention;

FIG. 11 is a flow diagram illustrating a method in accordance with one embodiment of the invention; and

FIG. 12 is a flow diagram illustrating a method in accordance with one embodiment of the invention.

### DETAILED DESCRIPTION OF ILLUSTRATIVE EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

For the purposes of the present invention, the phrase “A/B” means A or B. For the purposes of the present invention, the phrase “A and/or B” means “(A), (B), or (A and B).” For the purposes of the present invention, the phrase “at least one of A, B, and C” means “(A), (B), (C), (A and B), (A and C), (B and C), or (A, B and C).” For the purposes of the present invention, the phrase “(A)B” means “(B) or (AB),” that is, A is an optional element.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

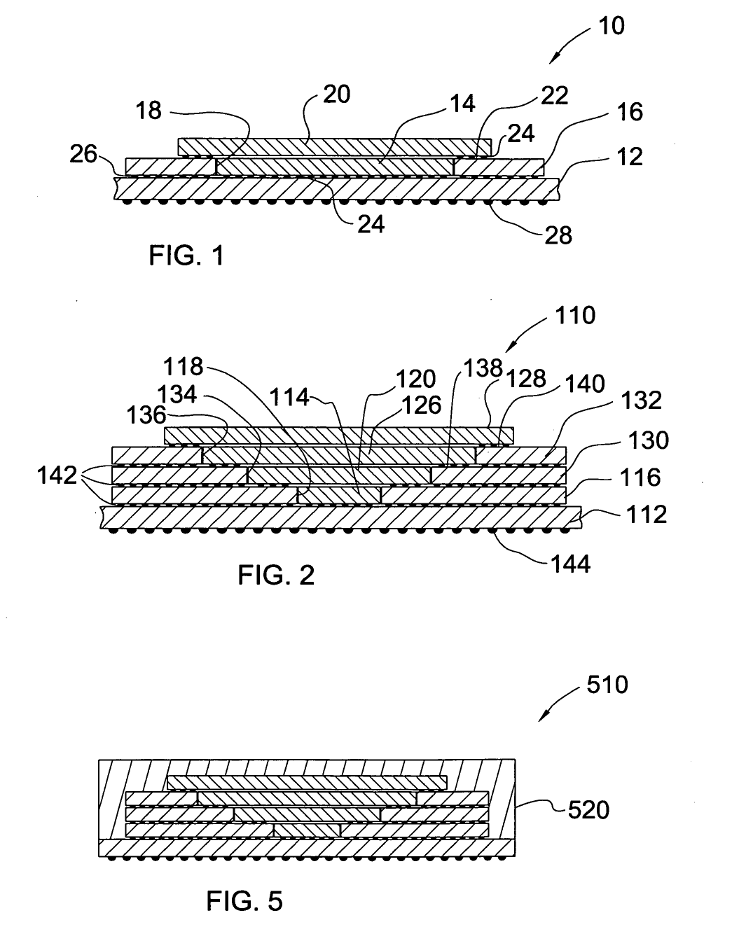

FIG. 1 is a cross sectional view illustrating various embodiments of the invention. As shown, for the embodiments, a die stack 10 includes a first substrate 12, a first die 14 bonded to the first substrate 12, a second substrate 16 having a cavity 18 sized and shaped to fit over the first die 14, and a second die 20 bonded to at least a portion of a rim 22 of the cavity 18. In various embodiments, the first die 14 in the die stack 10 may be flip-chip bonded 24 to the first substrate 12 and the second die 20 may be flip-chip bonded 24 to the at least a portion of the rim 22 and the cavity 18. The second substrate 16 may be bonded to the first substrate 12 with inter layer solder joints 26, which may be flip-chip bonds. The first substrate 12 may be bonded to, for example, a printed circuit board (not shown) with, for example, solder joints made from a ball grid array (BGA) 28.

FIG. 2 is another cross sectional view illustrating various embodiments of the invention. As shown, for the embodiments, a die stack 110 may include a first die 114 bonded to a first substrate 112, and a second die 120 bonded to a second substrate 116. The second substrate 116 may have a cavity 118 sized and shaped to fit over the first die 114. The die stack 110 may also include one or more additional die, for example, a third die 126 and a fourth die 128. The die stack 110 may also include one or more additional substrates, for example, a third substrate 130 and a fourth substrate 132. The third substrate 130 and the fourth substrate 132 may each have a cavity 134 and 136, respectively, sized and shaped to fit the respective second die 120, and the third die 126. Each of the respective third die 126 and the fourth die 128 may be bonded to at least a portion of a respective rim 138, 140 of the second and third cavities 134, 136 of the one or more additional, i.e., third and fourth substrates 130, 132.

In various embodiments, the third die 126 and the fourth die 128 stack 110 may be flip-chip bonded to the respective third and fourth substrates 130, 132 at least portions of the rims 138, 140 of the cavities 134, 136. The third and fourth substrates 130, 132 may be bonded to the respective second and third substrates 116, 130 with inter layer solder joints 142 which may be flip-chip bonds. The first substrate 112 may be bonded to, for example, a printed circuit board (not shown) with, for example, ball grid array (BGA) solder joints 144.

In various embodiments, one or more of the cavities may extend through the second substrate. Various embodiments may include one or more substrates having a cavity sized and shaped to fit over a die that extends only partway through the substrate.

The die stack 110 illustrated in FIG. 2 may include die that are progressively bigger than die below them on the stack. For example, the second die 120 may be bigger than the first die 114. Similarly the third die 126 may be bigger than the second die 120, and the fourth die 128 may be bigger than the third die 126. Various embodiments may have various numbers of die and substrates, and may include progressively bigger die as the layers of the stack are increased.

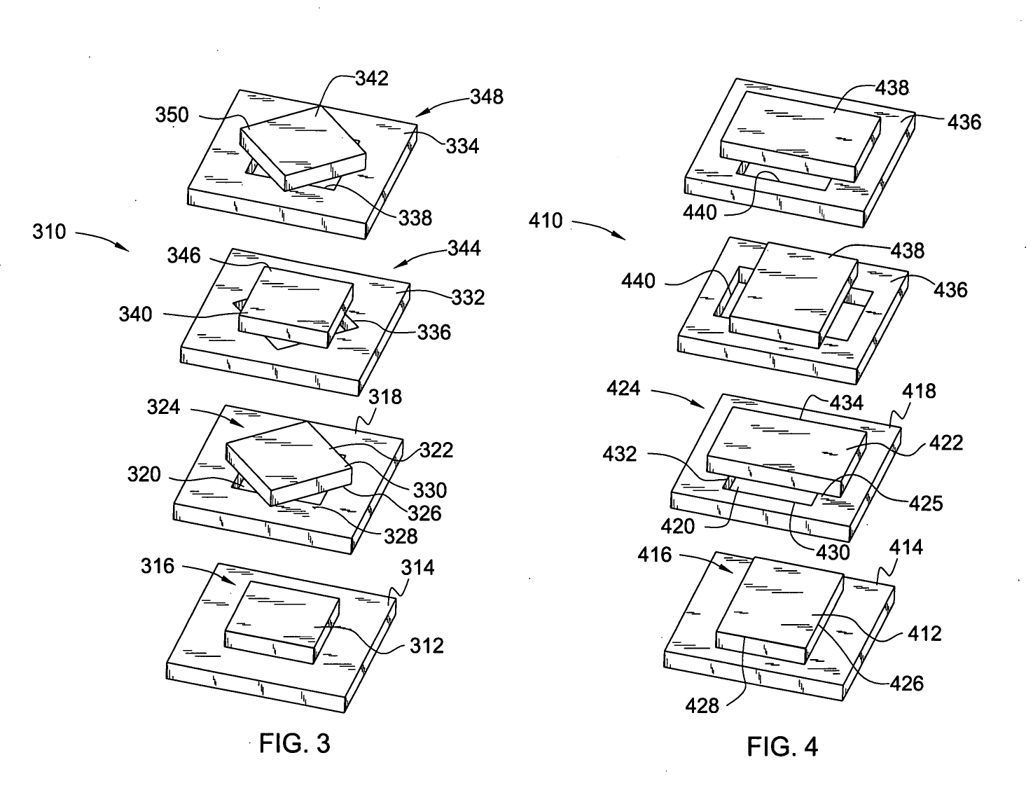

FIG. 3 is an exploded perspective view illustrating various embodiments of the invention. As shown, for the embodiments, a die stack 310 may include a first die 312 bonded to a first substrate 314 at a first orientation 316. A second substrate 318 may have a cavity 320 sized and shaped to fit over the first die 312. A second die 322 may be at a second orientation 324, for example, at an angle relative the cavity and/or the first die. The angle may be, for example, 45 degrees. The second die may then be bonded to at least a portion 326 of the rim 328 of the cavity 320 at corners 330 of the second die 322. The second substrate 318 may then be fit over the first die 312 and the second substrate 318 may be bonded to the first substrate 314.

In various embodiments, a third substrate 332 and a fourth substrate 334 may each include cavities 336 and 338 respectively sized and shaped to fit over the respective second die 322 and a third die 340 which may be bonded to the third substrate 332. A fourth die 342 may be bonded to the fourth substrate 334. The third die 340 may be at a third orientation 344 while the second cavity may be at the second orientation 324, and be bonded at corners 346 thereof. Similarly, the fourth die 342 may be at a fourth orientation 348 while the third cavity 338 may be at the third orientation 344 and be bonded at corners 350 thereof. In various embodiments, certain orientations may be repeated in a stack, for example, every other orientation may be the same. In various embodiments a stack may include die at various orientations.

FIG. 4 is another exploded perspective view illustrating various embodiments of the invention. As illustrated, for the embodiments, a die stack 410 has a first die 412 bonded to a first substrate 414. The first die 412 may be at a first orientation 416. A second substrate 418 may include a cavity 420 sized and shaped to fit over the first die 412. A second die 422 may be at a second orientation 424 and may be bonded to at least a portion of a rim 425 of the cavity 420. The first die 412 may be rectangular and may have a long dimension 426 and a short dimension 428, and the cavity 420 may also be rectangular and may have a long dimension 432 and a short dimension 430. The second die 422 may also be rectangular and be oriented such that a long dimension 434 of the second die 422 spans the short dimension 432 of the cavity 420.

In various embodiments, additional respective substrate(s) 436 and die(s) 438 may be added to the die stack and may include rectangular die(s) 438 and rectangular cavity(ies) 440. The die(s) 438 may be oriented such that a long dimension of the die(s) 438 spans a short dimension of the cavity(ies) 440.

FIG. 5 is another cross sectional view illustrating various embodiments of the invention. As illustrated, for the embodiments, a die stack 510 may be formed as a molded matrix array package (MMAP) 520. Various embodiments may be formed as other package types.

In various embodiments a second die may be above and bigger than a first die or oriented differently than the first die, and may include a third substrate having a second cavity sized and shaped to fit over the second die. A third die may be bonded to at least a portion of a rim of the second cavity and may be bigger than the second die or oriented differently than the second die.

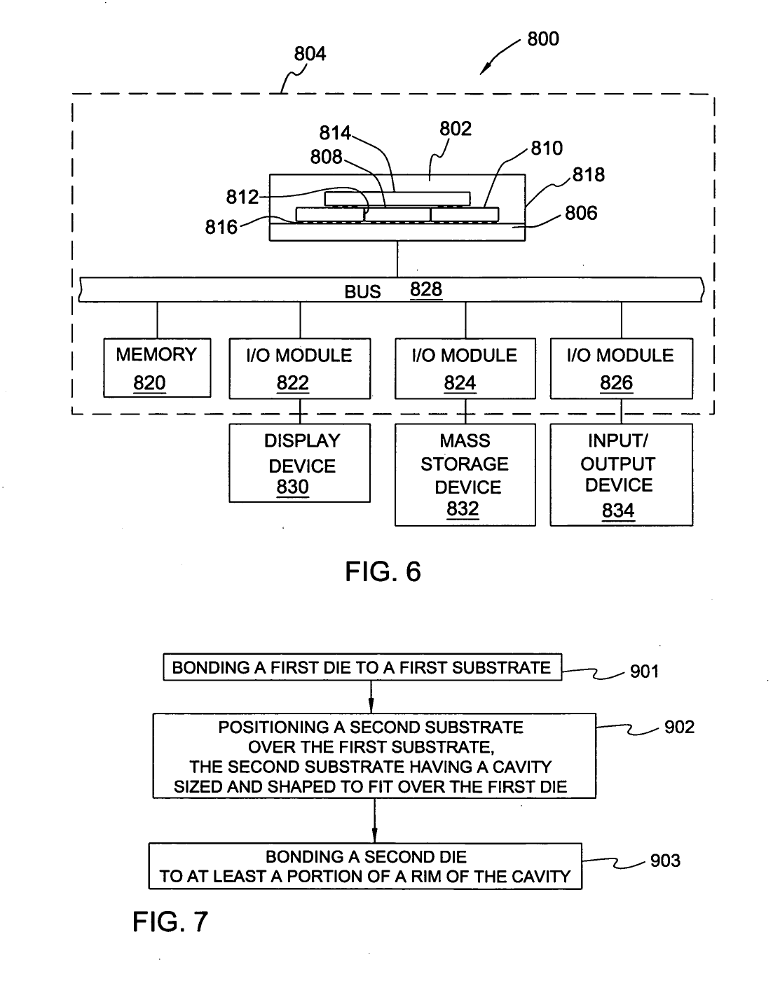

FIG. 6 illustrates a partial schematic and partial block diagram of a system 800 according to various embodiments of the invention, which is just a number of many possible systems in which one or more of the earlier described die stack embodiments may be used. In this illustrated system 800, a die stack may be an integrated circuit package 802 which may be a processor. The integrated circuit package 802 may be directly coupled to a printed circuit board (PCB) 804, represented here in dashed line, or indirectly coupled by way of a socket (not shown). The PCB 804 may be a motherboard. The integrated circuit package 802 may include a first substrate 806, a first die 808 bonded to the first substrate 806, and a second substrate 810 may have a cavity 812 sized and may be shaped to fit over the first die 808. A second die 814 may be bonded to at least a portion of a rim of the cavity 812. The second substrate 810 may be bonded to the first substrate with inter layer solder joints 816. The integrated circuit package may be formed into a package 818, for example, a molded matrix array package (MMAP).

Additionally, system 800 may include a main memory 820 and one or more, for example three, input/output (I/O) modules 822, 824, and 826. These elements including the earlier described integrated circuit package 802 may be coupled to each other via bus 828. The system 800 may further include a display device 830, a mass storage device 832 and an input/output (I/O) device 834 coupled to the bus 828 via respective input/output (I/O) modules 822, 824, and 826. Examples of the memory include, but are not limited to, static random access memory (SRAM) and dynamic random access memory (DRAM). The memory may also include cache memory. Examples of the display device may include, but are not limited to, a liquid crystal display (LCD), cathode-ray tube (CRT), light-emitting diode (LED), gas plasma, or other image projection technology. Examples of the mass storage device include, but are not limited to, a hard disk drive, a compact disk (CD) drive, a digital versatile disk (DVD) drive, a floppy diskette, a tape system, and so forth. Examples of the input/output (I/O) devices may include, but are not limited to, devices which may be suitable for communication with a computer user, for example, a keyboard, a mouse, a microphone, a voice recognition device, a display, a printer, speakers, and a scanner. The system may be included within, or include, a cell phone or a personal digital assistant (PDA).

Various embodiments according to the invention may include a system including an integrated circuit package with one or more additional die and one or more additional substrates each having a cavity respectively sized and shaped to fit over one of the second die or the one or more respective additional die. Each of the additional die may be bonded to at least a portion of a respective rim of the cavity of the one or more additional substrates. Various embodiments according to the invention may include a system wherein the first die is flip-chip bonded to the first substrate and the second die is flip-chip bonded to the at least a portion of the rim of the cavity. The cavity may extend through the second substrate, or in one embodiment may extend only partway through the substrate. In various embodiments according to the invention the second die may be bigger than the first die. In various embodiments according to the invention the first die may be at a first orientation and the second die may be at a second orientation. The second die may be bonded to the rim of the cavity at corners of the second die. In various embodiments according to the invention the first die may be rectangular and have a long dimension and a short dimension, and the cavity may be rectangular and have a long dimension and a short dimension, the second die may be oriented such that the long dimension of the second die spans the short dimension of the cavity.

Various embodiments according to the invention may include a system wherein a second die may be bigger than a first die, or may be oriented differently than the first die, and may further include a third substrate having a second cavity sized and shaped to fit over the second die. A third die may be bonded to at least a portion of a rim of the second cavity and may be bigger than the second die or may be oriented differently than the second die.

FIG. 7 is a flow diagram illustrating a method in accordance with various embodiments of the invention. The method may include:
bonding a first die to a first substrate 901;
positioning a second substrate over the first substrate, the second substrate having a cavity sized and shaped to fit over the first die 902; and
bonding a second die to at least a portion of a rim of the cavity 903.

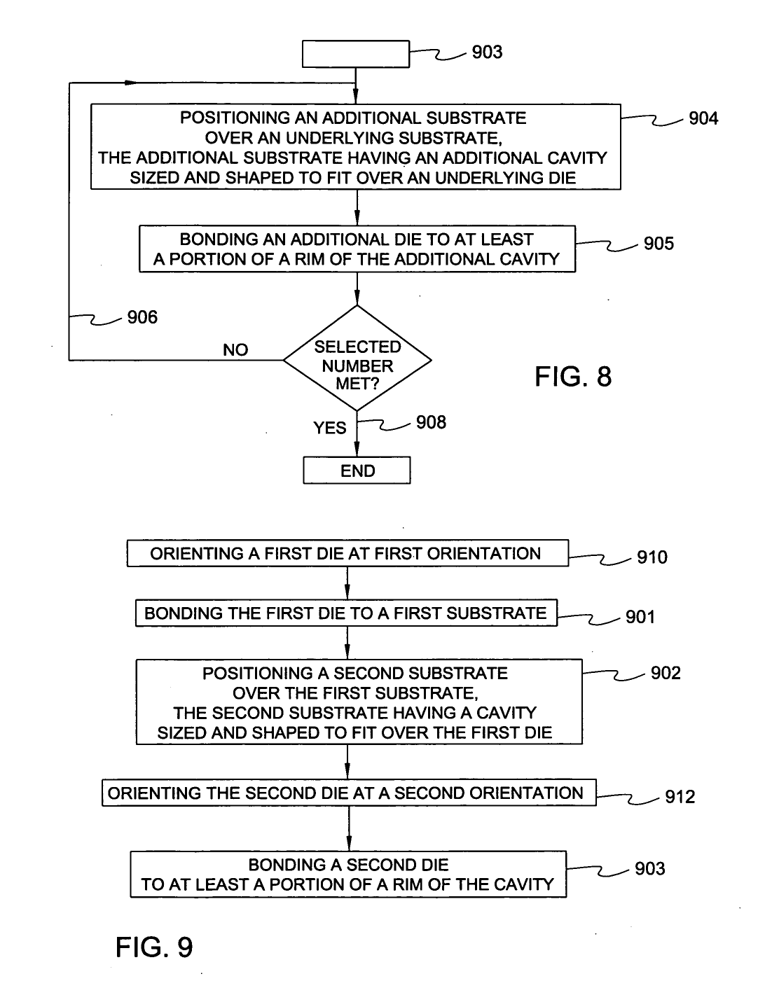

FIG. 8 is a flow diagram illustrating a method in accordance with various embodiments of the invention. The method may include operations similar to those illustrated in FIG. 7 and may further include:
positioning an additional substrate over an underlying substrate, the additional substrate having an additional cavity sized and shaped to fit over an underlying die 904; and
bonding an additional die to at least a portion of a rim of the additional cavity 905.

In various embodiments according to the invention, portions of the embodiment illustrated in FIG. 7 may be repeated. For example, as illustrated with line 906, in FIG. 8 one embodiment may include:
sequentially repeating the positioning of an additional substrate 904, and the bonding of an additional die 905 a selected number of one or more times with the selected number of additional substrate(s) and the selected number of additional die(s), the selected number being an integer equal to or greater than one. Upon reaching the selected number the sequential repeating 906 may end as illustrated in line 908.

In various embodiments according to the invention the bonding of the first die and the bonding of the second die such as illustrated in FIGS. 7 and 8 may be flip-chip bonding.

In various embodiments according to the invention, the cavity may extend through the second substrate. In various embodiments according to the invention, the second die may be bigger than the first die.

FIG. 9 is a flow diagram illustrating a method in accordance with one embodiment of the invention portions of the embodiment illustrated in FIG. 7 may be included here and may further include:

orienting the first die at a first orientation before the bonding the first die 910, and orienting the second die at a second orientation before the bonding the second die 912.

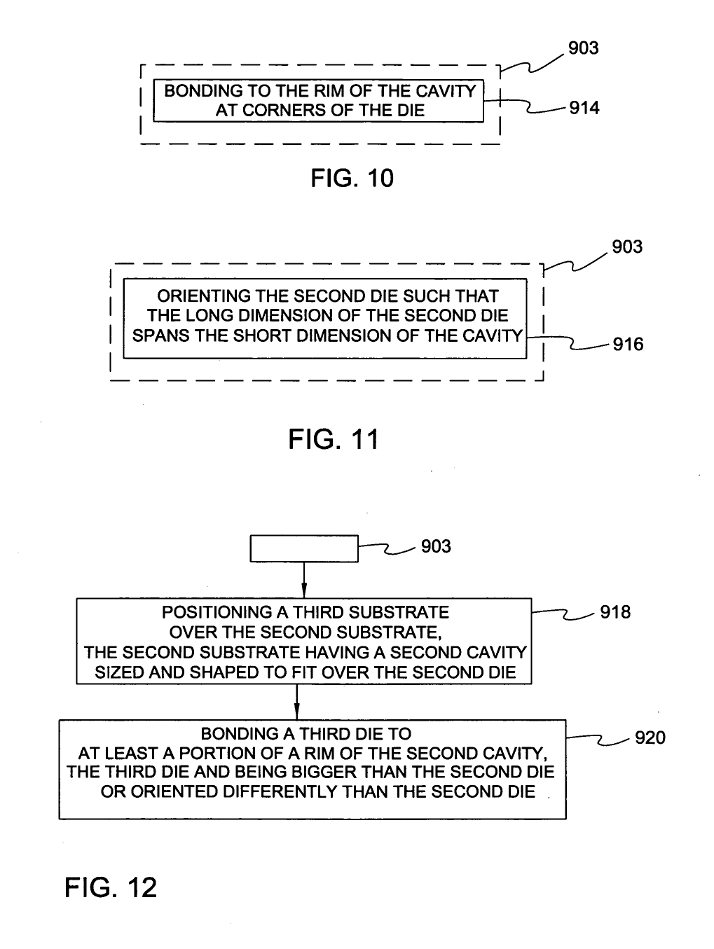

FIG. 10 is a flow diagram illustrating a method in accordance with one embodiment of the invention. Portions of the embodiment may include portions of the embodiment illustrated in FIG. 7, and wherein the bonding the second die 903 may include bonding to the rim of the cavity at corners of the die, 914.

FIG. 11 is a flow diagram illustrating a method in accordance with one embodiment of the invention. In various embodiments according to the invention: the first die may be rectangular and may have a long dimension and a short dimension, and the cavity may have a long dimension and a short dimension, the bonding the second die 903 may include orienting the second die such that the long dimension of the second die spans the short dimension of the cavity 916.

FIG. 12 is a flow diagram illustrating a method in accordance with one embodiment of the invention wherein the second die may be bigger than the first die or oriented differently than the first die. Portions of the embodiment illustrated in FIG. 7 may further comprise:
positioning a third substrate over the second substrate, the second substrate having a second cavity sized and shaped to fit over second die, 918; and
bonding a third die to at least a portion of a rim of the second cavity, the third die and being bigger than the second die or oriented differently than the second die, 920.

In various embodiments method may include molding a resultant stack into a molded matrix array package (MMAP).

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. A die stack comprising:
a first substrate;
a first die bonded to the first substrate;
a second substrate having a cavity sized and shaped to fit over the first die; and
a second die bonded to at least a portion of a rim of the cavity.

2. The die stack of claim 1 further comprising one or more additional die and one or more additional substrates each having a cavity respectively sized and shaped to fit over one of the second die or the one or more respective additional die, each of the additional die bonded to at least a portion of a respective rim of the cavity of the one or more additional substrates.

3. The die stack of claim 1 wherein the first die is flip-chip bonded to the first substrate and the second die is flip-chip bonded to the at least a portion of the rim of the cavity.

4. The die stack of claim 1 wherein the cavity extends through the second substrate.

5. The die stack of claim 1 wherein the second die is bigger than the first die.

6. The die stack of claim 1 wherein the first die is at a first orientation and the second die is at a second orientation.

7. The die stack of claim 6 wherein the second die is bonded to the at least a portion of the rim of the cavity at corners of the second die.

8. The die stack of claim 6 wherein the first die is rectangular and has a long dimension and a short dimension, and the cavity is rectangular and has a long dimension and a short dimension, the second die is oriented such that the long dimension of the second die spans the short dimension of the cavity.

9. The die stack of claim 1 wherein the second die is bigger than the first die or oriented differently than the first die, and further comprising a third substrate having a second cavity sized and shaped to fit over the second die, and a third die bonded to at least a portion of the second cavity and being bigger than the second die or oriented differently than the second die.

10. The die stack of claim 1 wherein the die stack is a molded matrix array package (MMAP).

11. A method comprising:
bonding a first die to a first substrate; positioning a second substrate over the first substrate, the second substrate having a cavity sized and shaped to fit over the first die; and
bonding a second die to at least a portion of a rim of the cavity.

12. The method of claim 11 further comprising:
positioning an additional substrate over an underlying substrate, the additional substrate having an additional cavity sized and shaped to fit over an underlying die; and
bonding an additional die to at least a portion of a rim of the additional cavity.

13. The method of claim 12 further comprising:
sequentially repeating the positioning of an additional substrate and the bonding of an additional die a selected number of one or more times with the selected number of additional substrate(s) and the selected number of additional die(s), the selected number being an integer equal to or greater than one.

14. The method of claim 11 wherein the bonding of the first die and the bonding of the second die are flip-chip bonding.

15. The method of claim 11 wherein the cavity extends through the second substrate.

16. The method of claim 11 wherein the second die is bigger than the first die.

17. The method of claim 11 further comprising orienting the first die at a first orientation before the bonding the first die and orienting the second die at a second orientation before the bonding the second die.

18. The method of claim 17 wherein the bonding the second die includes bonding to the rim of the cavity at corners of the die.

19. The method of claim 17 wherein the first die is rectangular and has a long dimension and a short dimension, and the cavity has a long dimension and a short dimension, the bonding the second die includes orienting the second die such that the long dimension of the second die spans the short dimension of the cavity.

20. The method of claim 11 wherein the second die is bigger than the first die or oriented differently than the first die, and further comprising:
positioning a third substrate over the second substrate, the second substrate having a second cavity sized and shaped to fit over second die; and
bonding a third die to at least a portion of a rim of the second cavity, the third die and being bigger than the second die or oriented differently than the second die.

21. A system comprising:
an integrated circuit package including a first substrate, a first die bonded to the first substrate, a second substrate having a cavity sized and shaped to fit over the first die, a second die bonded to at least a portion of a rim of the cavity; and
a mass storage coupled to the integrated circuit package.

22. The system of claim 21 wherein the integrated circuit package further comprising one or more additional die and one or more additional substrates each having a cavity respectively sized and shaped to fit over one of the second die or the one or more respective additional die, each of the additional die bonded to at least a portion of a respective rim of the cavity of the one or more additional substrates.

23. The system of claim 21 wherein the first die is flip-chip bonded to the first substrate and the second die is flip-chip bonded to the at least a portion of the rim of the cavity.

24. The system of claim 21 wherein the cavity extends through the second substrate.

25. The system of claim 21 wherein the second die is bigger than the first die.

26. The system of claim 21 wherein the first die is at a first orientation and the second die is at a second orientation.

27. The system of claim 26 wherein the second die is bonded to the rim of the cavity at corners of the second die.

28. The system of claim 26 wherein the first die is rectangular and has a long dimension and a short dimension, and the cavity is rectangular and has a long dimension and a short dimension, the second die is oriented such that the long dimension of the second die spans the short dimension of the cavity.

29. The system of claim 21 wherein the second die is bigger than the first die or oriented differently than the first die, and further comprising a third substrate having a second cavity sized and shaped to fit over the second die, and a third die bonded to at least a portion of the second cavity and being bigger than the second die or oriented differently than the second die.

30. The system of claim 21 wherein the integrated circuit package is a molded matrix array package (MMAP).
